(19) United States
(12) Patent Application Publication
(10) Pub. No.: US 2012/0024339 A1
(43) Pub. Date: Feb. 2, 2012

(54) Photovoltaic Module Including Transparent Sheet With Channel

(75) Inventor: Chris Eberspacher, Palo Alto, CA (US)

(73) Assignee: Applied Materials, Inc., Santa Clara, CA (US)

(21) Appl. No.: 13/190,827

(22) Filed: Jul. 26, 2011

Related U.S. Application Data
(60) Provisional application No. 61/367,907, filed on Jul. 27, 2010.

(51) Int. Cl. H01L 31/05; H01L 31/18

(52) U.S. Cl. 136/244; 438/66; 257/E31.117

(57) ABSTRACT

Photovoltaic modules and methods for making photovoltaic modules are disclosed. In one or more embodiments of the invention, the photovoltaic module includes a transparent sheet with a channel to accommodate a conductive member.

### CROSS-REFERENCE TO RELATED APPLICATIONS

This application claims the benefit under 35 U.S.C. §119(e) to U.S. Provisional Application No. 61/367,907, filed Jul. 27, 2010.

### BACKGROUND

Embodiments of the present invention relate generally to the field of photovoltaic cell manufacturing. More specifically, embodiments of the invention relate to photovoltaic cells and methods for rapidly manufacturing photovoltaic cells using transparent sheets having channels therein.

Photovoltaic devices or solar cells are devices which convert sunlight into direct current (DC) electrical power. Typical thin film type photovoltaic devices, or thin film solar cells, have one or more p-i-n junctions. Each p-i-n junction comprises a p-type layer, an intrinsic type layer, and an n-type layer. When the p-i-n junction of the solar cell is exposed to sunlight (consisting of energy from photons), the sunlight is converted to electricity through the photovoltaic effect. Solar cells may be tiled into larger solar arrays. The solar arrays are created by connecting a number of solar cells and joining them into panels with specific frames and connectors.

Typically, a thin film solar cell includes active regions, or photoelectric conversion units, and a transparent conductive oxide (TCO) film disposed as a front electrode and/or as a backside electrode. The photoelectric conversion unit includes a p-type silicon layer, an n-type silicon layer, and an intrinsic type (i-type) silicon layer sandwiched between the p-type and n-type silicon layers. Several types of silicon films, including microcrystalline silicon film (μ-Si), amorphous silicon film (a-Si), polycrystalline silicon film (poly-Si), and the like, may be utilized to form the p-type, n-type, and/or i-type layers of the photoelectric conversion unit. The backside electrode may contain one or more conductive layers.

Photovoltaic cells are typically electrically connected and encapsulated as a module. Photovoltaic modules typically have a transparent sheet on the front side (facing the sun), allowing light to pass while protecting the semiconductor wafers from the elements such as rain, snow, hail, etc. The transparent sheet also provides structural support. On the bottom of thin film photovoltaic modules, there is generally a second sheet such as the aforementioned glass materials. Photovoltaic modules are interconnected, in series or parallel, or both, to create an array with the desired peak DC voltage and current. A thin film photovoltaic layer and an encapsulating layer are typically sandwiched between the first and second sheets. The thickness of the encapsulating material layer may be in the range of about 10 microns to about 1000 microns, optionally between about 25 microns to about 500 microns, and optionally between about 50 to about 250 microns.

Photovoltaic modules typically incorporate wires, ribbons or braids as electricity-conducting means having a finite thickness that in turn must be embedded in the encapsulating material used to laminate the module. The finite thickness of the embedded conducting means partially determines the minimum thickness of the encapsulating material and affects the likelihood of the formation of bubbles or voids in the encapsulating material. In other words, thicker encapsulant layers are more prone to formation of bubbles or voids. There is a need for photovoltaic modules and methods of making photovoltaic modules which mitigate the impact the electricity-conducting means on the thickness and/or continuity of the encapsulating material.

### SUMMARY

One or more embodiments of the invention are directed to photovoltaic module comprising a first transparent substrate and a second substrate. The first substrate having a substantially flat inner surface and a channel formed in the inner surface. A plurality of photovoltaic cells is disposed between the first substrate and second substrate and a conductive element located in the channel formed in the inner surface. In detailed embodiments, the conductive element is in the form of a wire, ribbon or braid.

In some embodiments, the solar cell comprises a silicon solar cell and the conductive element is adhered to at least two solar cells.

In various embodiments, the solar cell comprises a thin film solar panel and the conductive member comprises a side buss to connect at least two cells for current capture.

In detailed embodiments, the channel is substantially rectangular in cross-section. In specific embodiments, the channel has a depth in the range of about 0.08 to 0.13 mm and a width in the range of about 3 to 5 mm.

The first transparent substrate of some embodiments is a front substrate having a back surface oriented to face a solar source. In detailed embodiments, the channel is formed by a plurality of raised surface features. In specific embodiments, the second substrate comprises a back substrate having an inner surface with a second channel substantially aligned with the channel in the first transparent substrate. In specific embodiments, the channel is formed by a plurality of raised surface features.

In some embodiments, the first transparent substrate has a peripheral edge and the channel is located adjacent the peripheral edge.

Additional embodiments of the invention are directed to methods of making a photovoltaic module. A first transparent substrate is provided having a substantially flat inner surface, and a channel formed in the inner surface. A plurality of photovoltaic cells is formed on the inner surface of the first substrate. A conductive element is disposed within the channel. The first substrate having the photovoltaic cells is laminated to a second substrate.

In detailed embodiments, laminating includes disposing encapsulating material between the first substrate and the second substrate and applying pressure to the substrates.

In specific embodiments, the photovoltaic module uses less encapsulating material than a similarly sized substrate without a groove formed in the first substrate.

In some embodiments, the first transparent substrate comprises a front substrate. In various embodiments, the transparent substrate comprises a back substrate.

In one or more detailed embodiments, only the front substrate has a channel formed therein. In one or more specific embodiments, a channel is formed in the second substrate that is aligned with the channel on the first substrate.

### BRIEF DESCRIPTION OF THE DRAWINGS

FIG. 1 is a side cross-sectional view of a thin film solar cell according to one or more embodiment of the invention;

FIG. 2 is a plan view of a composite photovoltaic module according to one or more embodiment of the invention;

FIG. 3A is end view of a front glass substrate according to one or more embodiments of the invention;

FIG. 3B is a bottom plan view of the front glass substrate shown in FIG. 3A having photovoltaic film deposited thereon according to one or more embodiments of the invention;

FIG. 4 a side cross-sectional view of a thin film photovoltaic module according to one or more embodiment of the invention;

FIG. 5A is a bottom plan view of a front glass substrate according to an alternative embodiment having photovoltaic film deposited thereon according to one or more embodiments of the invention;

FIG. 5B is a cross-sectional view taken along line 5B-5B of FIG. 5A;

FIG. 6A is a bottom plan view of a front glass substrate according to an alternative embodiment having photovoltaic film deposited thereon according to one or more embodiments of the invention;

FIG. 6B is a cross-sectional view taken along line 6B-6B of FIG. 6A;

FIG. 7A is a bottom plan view of a front glass substrate according to an alternative embodiment having photovoltaic film deposited thereon according to one or more embodiments of the invention;

FIG. 7B is a cross-sectional view taken along line 7B-7B of FIG. 7A;

FIG. 8A a side cross-sectional view of a thin film photovoltaic module utilizing the front glass sheet shown in FIG. 5A according to one or more embodiments of the invention; and

FIG. 8B is an enlarged partial perspective view showing a conductive member in contact with a photovoltaic film on the front glass substrate according to one or more embodiments.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

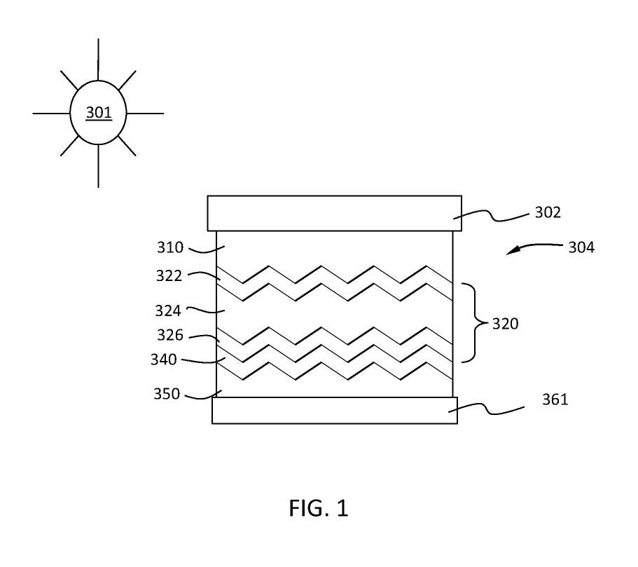

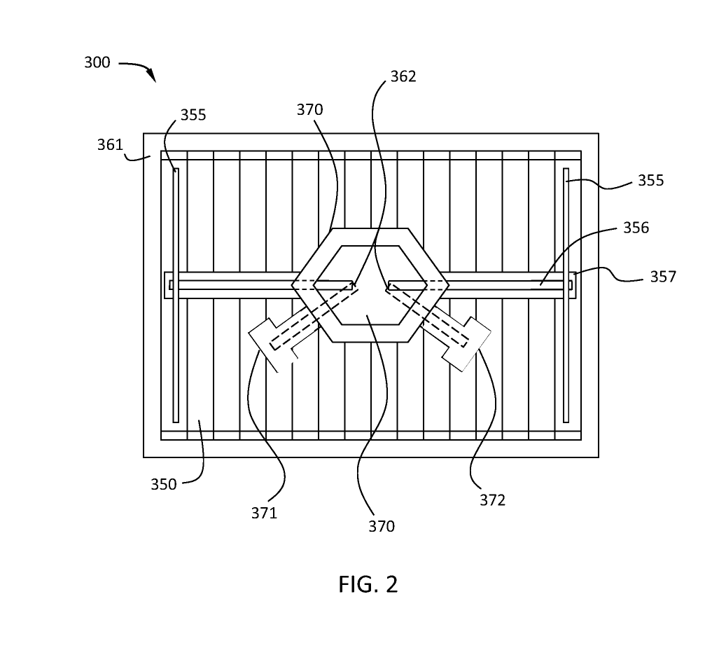

An example of a photovoltaic cell 304 that forms part of a module is illustrated in FIGS. 1 and 2. FIG. 1 is a simplified schematic diagram of a single junction amorphous silicon photovoltaic cell 304. As shown in FIG. 1, the single junction amorphous silicon photovoltaic cell 304 is oriented toward a light source or solar radiation 301. The cell 304 generally comprises a first or front transparent substrate 302, such as a glass substrate having a back surface oriented towards solar radiation 301, polymer substrate, or other suitable substrate, with thin films formed thereover. Nonlimiting examples of suitable materials of the first or front transparent substrate include conventional glass, solar glass, high-light transmission glass with low iron content, standard light transmission glass with standard iron content, anti-glare finish glass, tempered glass, heat-strengthened glass, annealed glass, or combinations thereof. In one embodiment, the first or front substrate 302 is a glass substrate that is about 2200mm×2600 mm×3 mm in size. The substrate is a substantially flat sheet. The cell further comprises a first transparent conducting oxide (TCO) layer 310 (e.g., zinc oxide (ZnO), tin oxide (SnO)) formed over an inner surface of the substrate 302, a first p-i-n junction 320 formed over the first TCO layer 310, a second TCO layer 340 formed over the first p-i-n junction 320, and a back contact layer 350 formed over the second TCO layer 340. To improve light absorption by enhancing light trapping, the substrate and/or one or more of the thin films formed thereover may be optionally textured by wet, plasma, ion, and/or mechanical processes. For example, in the embodiment shown in FIG. 1, the first TCO layer 310 is textured, and the subsequent thin films deposited thereover generally follow the topography of the surface below it.

In one configuration, the first p-i-n junction 320 may comprise a p-type amorphous silicon layer 322, an intrinsic type amorphous silicon layer 324 formed over the p-type amorphous silicon layer 322, and an n-type microcrystalline silicon layer 326 formed over the intrinsic type amorphous silicon layer 324. In one example, the p-type amorphous silicon layer 322 may be formed to a thickness between about 60 Å and about 300 Å, the intrinsic type amorphous silicon layer 324 may be formed to a thickness between about 1,500 Å and about 3,500 Å, and the n-type microcrystalline silicon layer 326 may be formed to a thickness between about 100 Å and about 400 Å. The back contact layer 350 may include, but is not limited to, a material selected from the group consisting of Al, Ag, Ti, Cr, Au, Cu, Pt, Ni, Mo, conductive carbon, alloys thereof, and combinations thereof. It is to be understood that the cell shown in FIG. 1 is exemplary only, and the invention is not limited to any particular thin film solar cell layering or material structure. The cell may also be in the form of a multi-junction photovoltaic module. As shown in FIG. 1, a second or back substrate 361 is bonded to the front transparent substrate 302 by an encapsulating material using a laminating process. The back substrate 361 is oriented with an inner surface in contact with the encapsulating material and a back surface opposite the inner surface. The back substrate can be made from any of the materials used for the first or front substrate, except that metal foils or combination of metal foils with glass and/or polymeric materials can be used.

FIG. 2 is a bottom plan view of a photovoltaic module 300 comprised of a plurality of photovoltaic cells of the type shown in FIG. 1. In one or more embodiments, a bonding wire or ribbon is used to form conductive members, which may be referred to as a side-buss 355 and cross-buss 356 on the formed back contact layer 350 shown in FIG. 1. In one embodiment, the side-buss 355 and cross-buss 356 each comprise a metal strip, such as copper tape, a nickel coated silver ribbon, a silver coated nickel ribbon, a tin coated copper ribbon, a nickel coated copper ribbon, or other conductive material that can carry current delivered by the photovoltaic module 300 and that can be reliably bonded to the back contact layer 350 in the back contact region. In one embodiment, the metal strip is between about 2 mm and about 10 mm wide and between about 1 mm and about 3 mm thick. As discussed above, because the side buss 355 has a finite thickness, the additional thickness requires additional encapsulating material to accommodate and provide for the thickness of the side buss 355. In one or more embodiments, the groove or channel has a depth to accommodate the conductive member, for example in the range of about 3 to 5 mils (0.08 to 0.13 mm) and a width in the range of about 3 to 5 mm such that the conductive member is embedded within the substrate, requiring less bonding or encapsulating material than in a module that does not have grooves or channels formed in the substrate.

The cross-buss 356, which is electrically connected to the side-buss 355 at junctions, can be electrically isolated from the back contact layer(s) 350 of the photovoltaic module 300 by use of an insulating material 357, such as an insulating tape. The ends of each of the cross-busses 356 generally have one or more leads 362 that are used to connect the side-buss 355 and the cross-buss 356 to the electrical connections found in a junction box 370 (i.e., two junction box terminals 371, 372), which is used to connect the formed photovoltaic module 300 to other external electrical components.

A bonding material or encapsulating material are used to bond the first or front transparent substrate 302 and second or back substrate 361 and to laminate the two substrates 302, 361 together. The back substrate 361 is bonded onto the front transparent substrate 302 by a laminating process, for example, by placing a polymeric material between the back substrate 361 and the deposited layers on the front transparent substrate 302 to form a hermetic seal to prevent the environment from attacking the solar cell during its life.

In an exemplary process, the front transparent substrate 302 containing the photovoltaic layers, the back substrate 361, and the bonding material are transported to a bonding module in which lamination steps are performed to bond the back substrate 361 to the front transparent substrate 302. In a specific embodiment, an encapsulating or bonding material may be sandwiched between the back substrate 361 and the front transparent substrate 302. Suitable encapsulating or bonding materials include, but are not limited to ethyl vinyl acetate (EVA), polyvinyl butyral (PVB), ionomer, silicone, thermoplastic polyurethane (TPU), thermoplastic elastomer polyolefin (TPO), tetrafluoroethylene hexafluoropropylenevinylidene (THV), fluorinated ethylene-propylene (FEP), saturated rubber, butyl rubber, thermoplastic elastomer (TPE), flexibilized epoxy, epoxy, amorphous polyethylene terephthalate (PET), urethane acrylic, acrylic, other fluoroelastomers, and a variety of other materials of similar qualities, or combinations thereof.

Heat and pressure are applied to the structure to form a bonded and sealed device using various heating elements and other devices. The front transparent substrate 302, the back substrate 361, and the bonding material thus form a composite photovoltaic module 300 that at least partially encapsulates the active regions of the solar cell device. In some embodiments, at least one hole formed in the back substrate 361 remains at least partially uncovered by the bonding material to allow portions of the cross-buss 356 or the side-buss 355 to remain exposed so that electrical connections can be made to these regions of the photovoltaic module 300.

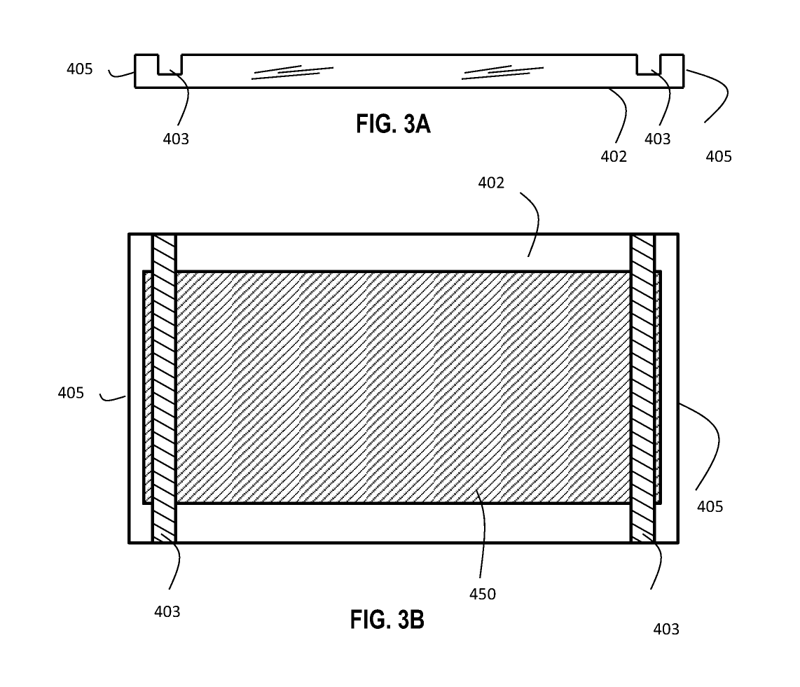

FIG. 3A is an end view of a first or front transparent substrate 402 according to one or more embodiments of the invention. As shown in FIG. 3A, first or front transparent substrate 402 has at least one groove or channel 403 formed adjacent edge 405. In the embodiment shown, a second groove or channel 403 is formed adjacent the edge 405 of the first or front transparent substrate 402. FIG. 3B shows a bottom plan view of an inner surface of substrate 402 with back contact layer 450 deposited on the substrate.

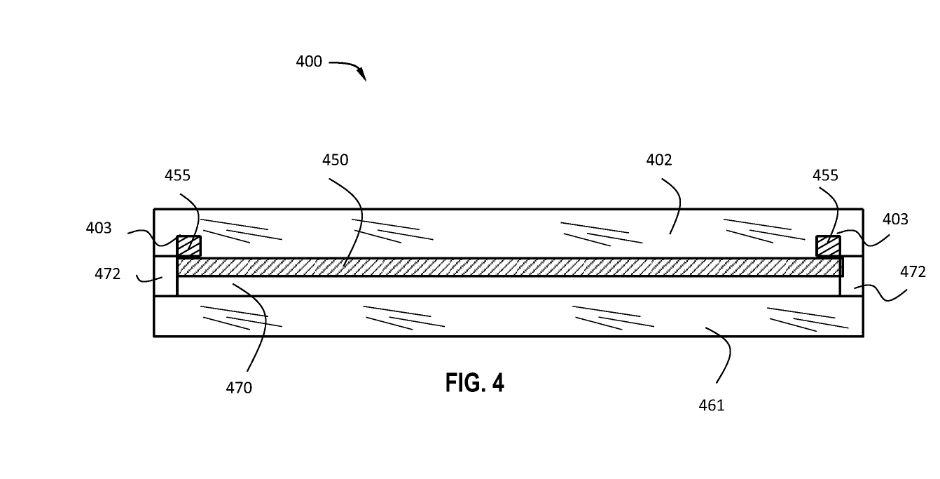

FIG. 4 shows a cross-sectional view of a photovoltaic module 400 including the first front glass substrate 402 including grooves or channels 403 and back contact layer 450 deposited on the first or front glass substrate 402. For ease of illustrate and reference, the underlying layers of the photovoltaic cells, for example, those shown in FIG. 1, are not shown in FIG. 4. The photovoltaic module further includes a second or back glass substrate 461, and the module is laminated together with an encapsulating material 470 of the type described above. The module 400 may be sealed on the edges with an edge sealing material 472 or sealing tape. As shown in FIG. 4, conductive member 455 is disposed within groove or channel 403. The conductive member 455 according to one or more embodiments may be a side buss.

The grooves or channels 403 in the first or front glass substrate 402 can be provided during the initial substrate forming process, for example by molding, or alternatively, the grooves or channels 403 can be formed by grinding, etching or other means as might be used to effect three-dimensional shapes in on otherwise flat substrate. It will be appreciated that grooves or channels 403 will minimize disruption of packaging topology of, for example, conductive members such as busses, for example, the conductive member 455 as shown in FIG. 4. Such conductive members may be in the form of relatively thick metal ribbons, braids or wires used for conducting electrical power from photoactive areas of a photovoltaic device. The grooves or channels may also minimize disruption of packing topology of edge sealing tape or other structures between the substrates 402, 461 that require additional encapsulating material 470. As discussed above, as more encapsulating material 470 is required, as the thickness of the encapsulating material 470 layer thickness increases, there is a greater likelihood of formation of voids or bubbles in the encapsulating material 470. By providing grooves or channels 403 to accommodate the topology electrically conductive members, the amount and thickness of the encapsulating material 470 can be minimized, thus reducing the propensity to form voids or bubbles in the encapsulating material 470.

In a specific embodiment, the grooves or channels 403 comprise a molded channel with a rectangular cross-channel profile. However, the invention is not limited to a particular shape or cross section. A similar topology to the grooves or channels 403 could be effected on a substrate on which a thin-film solar cell is fabricated, on a substrate on which wafer or flex cells are mounted, or on a cover sheet that is attached to the original substrate or cells as a protective member. It will be appreciated that the topology provided by the grooves or channels can reduce the manufacturing cost of a photovoltaic module by reducing the volumetric amount of encapsulating material needed to assure a void-free encapsulation.

It will be understood that while the embodiment shown shows a pair of grooves or channels 403, the present invention is not limited to any number of grooves or channels. The grooves or channels could be placed adjacent all four edges (the peripheral edge) of a substrate such that a channel or groove bounds the periphery or peripheral edge of the substrate. It will also be understood that additional grooves or channels could be formed in the substrate to accommodate the topology of conductive members in the form of wires, ribbons or braids that may be within the photovoltaic module such as a cross-buss (for example cross-buss 356 as shown in FIG. 2). It will also be understood that the invention is not limited to the formation of grooves or channels in a single substrate such that the first or front substrate shown in FIGS. 3A, 3B and 4. Thus, the first or front substrate may not include grooves or channels and the second or back substrate may include grooves or channels to accommodate conductive members in the photovoltaic module. In an alternative embodiment, both the first or front substrate and second or back substrate may both have grooves formed therein to accommodate the topology of conductive members so that the conductive members are disposed within the channels or grooves. In embodiments in which a groove or channel is formed in the front and back substrate, the grooves or channel in each substrate may be aligned. Alignment of the grooves may be desirable to reduce the depth of the groove formed in the glass substrate, which, if the groove or channel is too deep, may compromise the strength of the substrate. Thus, it may be desirable for the grooves to be complementary and located so that they cooperate to form a thicker groove or channel than in each substrate alone. As is readily understood by the skilled artisan, the surface of the substrate facing solar radiation or the environment is referred to an a back surface or outer surface and the surface of each substrate enclosing the photovoltaic cells may be referred to as an inner surface of the substrate. As noted above, the provision of such channels or grooves to accommodate and house the conductive members results in a photovoltaic module that utilizes less encapsulating material than a similarly sized module that does not have grooves or channels for the conductive members.

Further embodiments of the invention are directed to methods of making a photovoltaic module 400. The methods comprise forming a plurality of solar cells as described above. This can be done as described above, or according to other methods known to those skilled in the art. At least one groove or channel 403 is formed in at least one of the first or second substrate. The groove or channel is positioned to accommodate our house a conductive member such that the conductive member is disposed within the groove or channel. The conductive member may be a member such as a side buss or cross-buss to connect a plurality of solar cells. As used herein, the term “buss” refers to an electrical connection between solar cells, including solar modules made from interconnected silicon cells or solar modules that are made from interconnected thin film solar cells. As is understood by the skilled artisan, silicon solar cells are typically connected by a buss wire. For solar modules or solar panels made from thin film solar cells, the end solar cells are connected by a side buss connecting the end cells for current capture. Thus, the term “buss” is broadly intended to include a connection between solar cells, whether the connection is between two silicon solar cells, or between two thin film solar cells. The first substrate and a second substrate are then laminated together using a bonding material or encapsulating material as described above to form a photovoltaic module. The conductive member is disposed within the groove or channel such that the amount of bonding material or encapsulating material required to laminate the first substrate and second substrate is less than is needed to laminate two substrates of a similarly sized photovoltaic module that does not have a groove or channel to accommodate the conductive member.

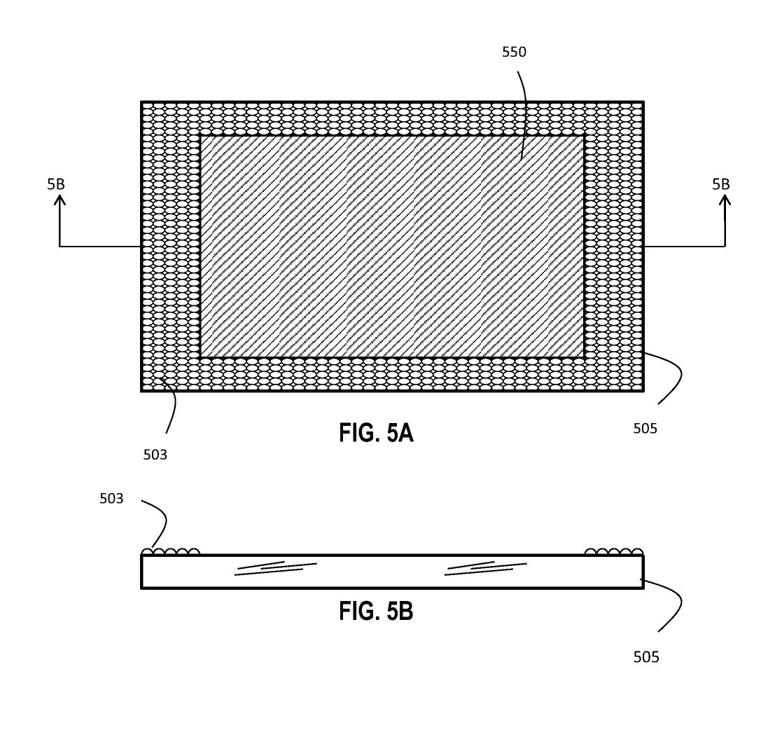

It will be appreciated that the groove or channel to accommodate the conductive member does not have to be configured as shown in FIGS. 3A and 3B. FIGS. 5A and 5B show a superstrate or cover glass 505 including a back contact 550 and raised features 503 that facilitate attaching a back plane such as another sheet of glass, a metal foil, a polymeric sheet or some combination of glass, foil and polymer. The raised features 503 facilitate attaching a back plane are located in regions of the perimeter or near where conductive members such as electrical leads might exit and a junction box is to be attached, where said raised features in said regions include pre-formed topology. As shown in FIGS. 5A and 5B the raised features are in the form of roughness, which may be embossed surface features or mounds which could be deposited by a variety of techniques. The raised features 503 could also be formed by depositing a composition such as a low-softening temperature glass, which can then be formed by printing, texturing etc to form the raised surface features. (e.g. roughness, texture, voids, striations, embossing, deposited mounds) or pre-formed compositions

It will be appreciated that the surface features can also effect or improve an edge seal where said features include pre-formed topology (e.g. striations, embossing, deposited mounds) or post-solar-cell-formed topology (e.g. effected by grooving, striating, etching, etc.). According to conventional processes, the attachment of electrical leads and the sealing of the perimeter and any lead feed-through holes add cost and complexity to the packaged module. Similarly, wafer or flex cell modules are often packaged in a glass/backsheet structure in which the PV cells are encapsulated between a glass sheet and a protective backsheet, wherein the electrical interconnection of cells, the attachment of electrical leads, and the sealing of the perimeter and any lead feed-through holes add cost and complexity to the PV module manufacturing process. Embodiments of the invention seek to reduce the cost and complexity of module packaging by providing facilitating features on the front glass sheet, be it a thin-film PV superstrate or a wafer or flex cell cover.

It will be appreciated that the raised surface features can also facilitate effecting durable seals around electrodes that carry electrical power from an encapsulated photovoltaic means to the outside world, where said features include pre-formed topology (e.g. roughness, texture, voids, striations, embossing, deposited mounds) or pre-formed compositions (e.g. areas of sealable materials such as low-softening-temperature glass deposited on and/or embedded in the superstrate). The raised surface features may be formed by shaping the same material as is the bulk composition of the superstrate, or may be formed by shaping a material different from that of the bulk superstrate. The raised surface features may be additive, e.g. another material or feature added to a previously complete and finished superstrate; or may be inherent, e.g. a specialized feature formed at about the same time as the original superstrate. It will be understood that the raised surface features may be present on a substrate instead of a superstrate.

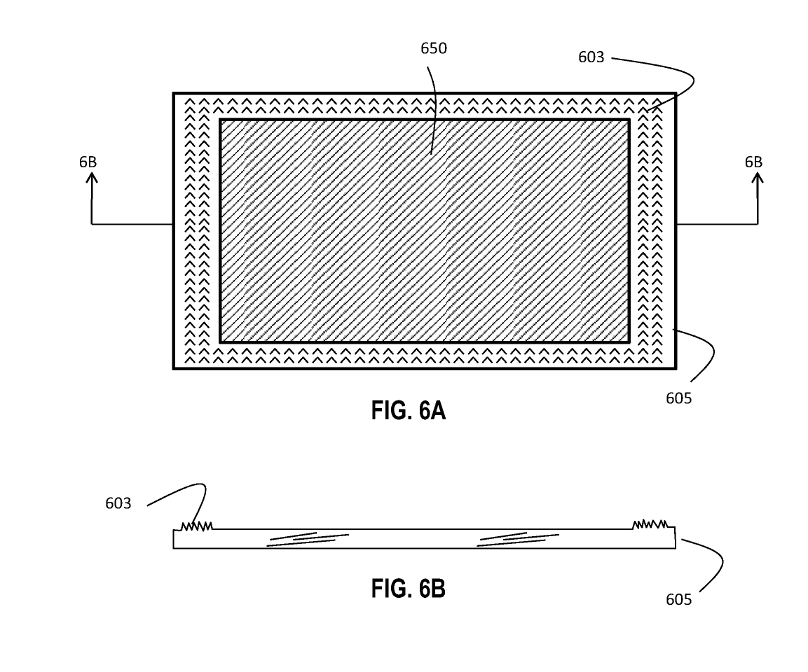

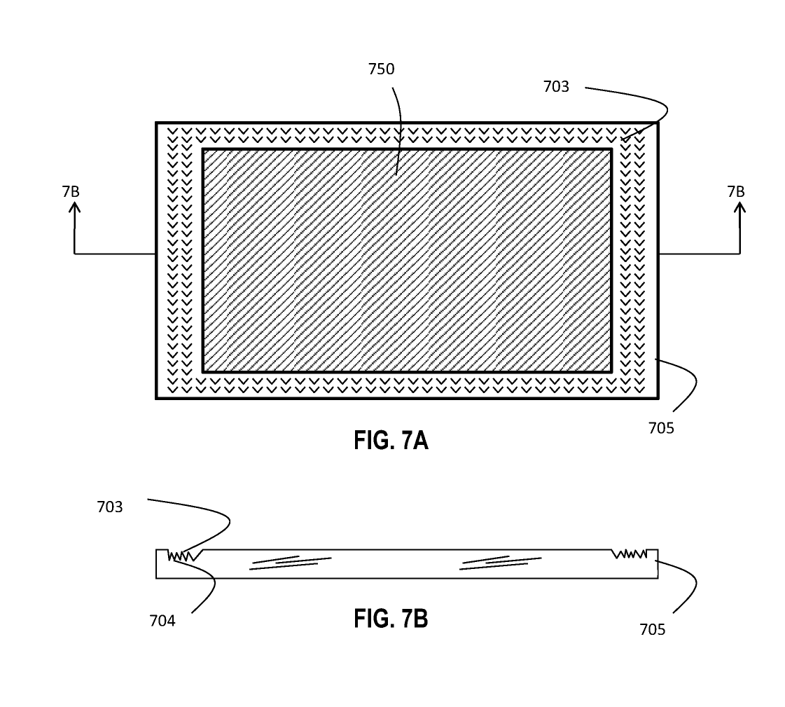

FIGS. 6A and 6B shows another example of raised surface features 603 on a superstrate 605 or cover glass having a back contact 650 deposited on the superstrate 605. In FIGS. 6A and 6B, the raised surface features are in the form of grooves that can be formed by any of a variety of techniques described above. FIGS. 7A and 7B show an embodiment in which striations or patterned grooves 703 are formed within a primary channel 704 of a superstrate 705 having a back contact 750 formed thereon. These features can be formed by any of a variety of techniques described above.

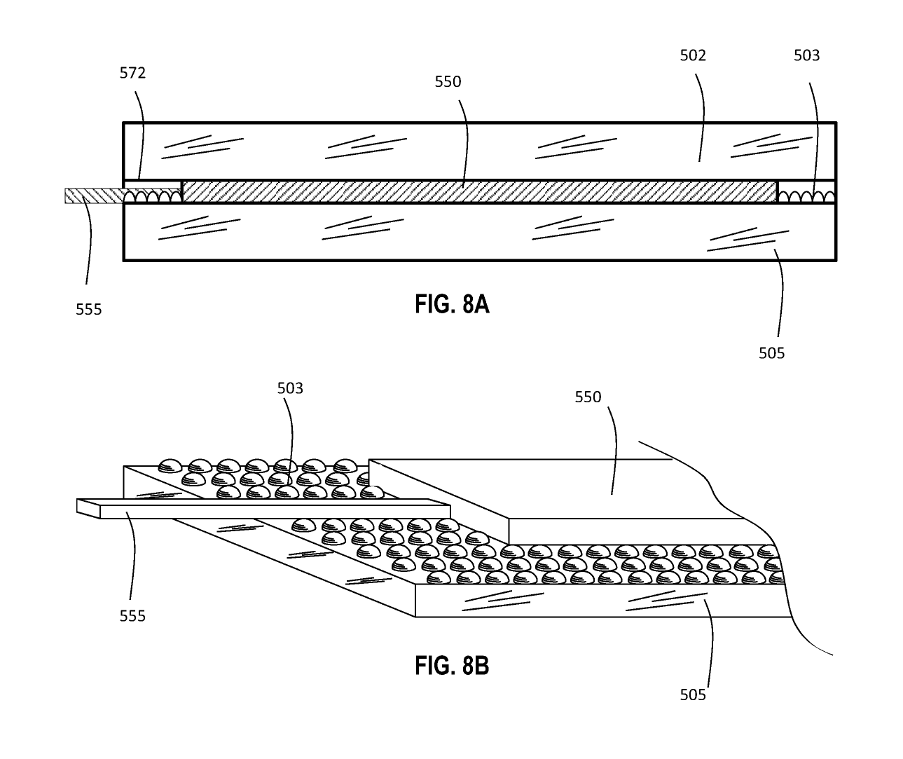

FIGS. 8A and 8B show how raised surface features of the type shown in FIG. 8 shows a cross-sectional view of a photovoltaic module including the first front glass substrate 502 including raised features 503 and back contact layer 550 deposited on the first or front glass substrate 502. For ease of illustration and reference, the underlying layers of the photovoltaic cells, for example, those shown in FIG. 1, are not shown in FIG. 8. The photovoltaic module further includes a second or back glass substrate 561, and the module is laminated together with an encapsulating material of the type described above. The module 4 may be sealed on the edges with an edge sealing material 572 or sealing tape. As shown in FIG. 8, conductive member 555 is disposed within groove or channel between raised surface features 503. The conductive member 455 according to one or more embodiments may be a side buss.

Although the invention herein has been described with reference to particular embodiments, it is to be understood that these embodiments are merely illustrative of the principles and applications of the present invention. It will be apparent to those skilled in the art that various modifications and variations can be made to the method of the present invention without departing from the spirit and scope of the invention. Thus, it is intended that the present invention include modifications and variations that are within the scope of the appended claims and their equivalents.

What is claimed is:

1. A photovoltaic module comprising:
a first transparent substrate having a substantially flat inner surface, and a channel formed in the inner surface;
a second substrate;
a plurality of photovoltaic cells disposed between the first substrate and second substrate; and
a conductive element located in the channel formed in the inner surface.

2. The photovoltaic module of claim 1, wherein the conductive element is in the form of a wire, ribbon or braid.

3. The photovoltaic module of claim 1, wherein the plurality of photovoltaic cells comprise a silicon solar cell and the conductive element is adhered to at least two photovoltaic cells.

4. The photovoltaic module of claim 1, wherein the plurality of photovoltaic cells comprise a thin film solar panel and the conductive element comprises a side buss to connect at least two photovoltaic cells for current capture.

5. The photovoltaic module of claim 1, wherein the channel is substantially rectangular in cross-section.

6. The photovoltaic module of claim 5, wherein the channel has a depth in the range of about 0.08 to 0.13 mm and a width in the range of about 3 to 5 mm.

7. The photovoltaic module of claim 1, wherein the first transparent substrate is a front substrate having a back surface oriented to face a solar source.

8. The photovoltaic module of claim 7, wherein the channel is formed by a plurality of raised surface features.

9. The photovoltaic module of claim 7, wherein the second substrate comprises a back substrate having an inner surface with a second channel substantially aligned with the channel in the first transparent substrate.

10. The photovoltaic module of claim 1, wherein the first transparent substrate has a peripheral edge and the channel is located adjacent the peripheral edge.

11. A method of making a photovoltaic module, comprising:
providing a first transparent substrate having a substantially flat inner surface, and a channel formed in the inner surface;
forming a plurality of photovoltaic cells on the inner surface of the first substrate;
disposing a conductive element within the channel; and
laminating the first substrate having the photovoltaic cells to a second substrate.

12. The method of claim 11, wherein the laminating includes disposing encapsulating material between the first substrate and the second substrate and applying pressure to the substrates.

13. The method of claim 12, wherein the photovoltaic module uses less encapsulating material than a similarly sized substrate without a groove formed in the first substrate.

14. The method of claim 12, wherein the first transparent substrate comprises a front substrate.

15. The method of claim 14, wherein the transparent substrate comprises a back substrate.

16. The method of claim 15, wherein only the front substrate has a channel formed therein.

17. The method of claim 15, wherein a channel is formed in the second substrate that is aligned with the channel on the first substrate.

18. The method of claim 17, wherein the channel is substantially rectangular in cross-section.

19. The method of claim 18, wherein the channel has a depth in the range of about 0.08 to 0.13 mm and a width in the range of about 3 to 5 mm.

20. The method of claim 11, wherein the channel is formed by a plurality of raised surface features.
